(19) United States
(12) Patent Application Publication
(10) Pub. No.: US 2002/0039285 A1
(43) Pub. Date: Apr. 4, 2002

(54) Device for reducing electromagnetic interference in a processor assembly

(76) Inventors: Jeremy Hsieh, Taipei Hsien (TW); Eddy Kao, Taipei Hsien (TW); Ko-Chen Tan, Taipei Hsien (TW); Jimmy Wang, Taipei Hsien (TW)

Correspondence Address: PILLSBURY WINTHROP LLP, East Tower Ninth Floor, 1100 New York Avenue, Washington, DC, 20005-3918, US

(21) Appl. No.: 09/886,983

(22) Filed: Jun. 25, 2001

(30) Foreign Application Priority Data
Sep. 30, 2000 (TW) 089217014

(51) Int. Cl. H05K 7/14

(52) U.S. Cl. 361/799

(57) ABSTRACT

A device for reducing electromagnetic interference is adapted for use in a processor assembly that includes a circuit board with opposite first and second sides, a processor socket mounted on the first side of the circuit board and connected electrically to the circuit board, a central processing unit having a heat-dissipating side and a contact side that is opposite to the heat-dissipating side and that is mounted on and connected electrically to the processor socket, and a conductive heat sink in contact with the heat-dissipating side of the central processing unit. The device includes a grounding spring plate having a first end portion adapted to contact the heat sink and a second end portion adapted to be mounted on the circuit board so as to connect electrically with a ground terminal of the circuit board, thereby establishing electrical connection between the heat sink and the ground terminal.

### BACKGROUND OF THE INVENTION

1. Field of the Invention

The invention relates to a device for reducing electromagnetic interference in a processor assembly, more particularly to a device that is simple in construction, that is highly flexible in terms of arrangement, and that can effectively reduce electromagnetic interference.

2. Description of the Related Art

As the current trend in both the electronic and computer industries is toward miniaturization, the distribution of electronic components on integrated circuit boards has become dense. Since all electronic components generate electromagnetic waves during operation thereof, the dense arrangement of the electronic components will result in electromagnetic interference (EMI) , which can seriously affect the reliability and stability of a system if ignored. Central processing units are major sources of electromagnetic waves as they operate at very high speeds. However, conventional EMI-reducing devices are not directed to the reduction of the electromagnetic interference in the central processing units, and are largely configured to be mounted on a main board or a housing. The effect thereof is therefore unsatisfactory.

### SUMMARY OF THE INVENTION

Therefore, the main object of the present invention is to provide a device for reducing electromagnetic interference in a processor assembly which is simple in construction, which is highly flexible in terms of arrangement, and which can effectively reduce electromagnetic interference.

Accordingly, a device for reducing electromagnetic interference of this invention is adapted for use in a processor assembly that includes a circuit board with opposite first and second sides, a processor socket mounted on the first side of the circuit board and connected electrically to the circuit board, a central processing unit having a heat-dissipating side and a contact side that is opposite to the heat-dissipating side and that is mounted on and connected electrically to the processor socket, and a conductive heat sink in contact with the heat-dissipating side of the central processing unit. The device includes a grounding spring plate having a first end portion adapted to contact the heat sink and a second end portion adapted to be mounted on the circuit board so as to connect electrically with a ground terminal of the circuit board, thereby establishing electrical connection between the heat sink and the ground terminal.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of the preferred embodiment of a device for reducing electromagnetic interference according to the invention;

FIG. 2 is an exploded perspective view illustrating a processor assembly that incorporates the preferred embodiment; and

FIG. 3 is a fragmentary schematic view illustrating the processor assembly of FIG. 2.

### DETAILED DESCRIPTION OF THE PREFERRED EMBODIMENT

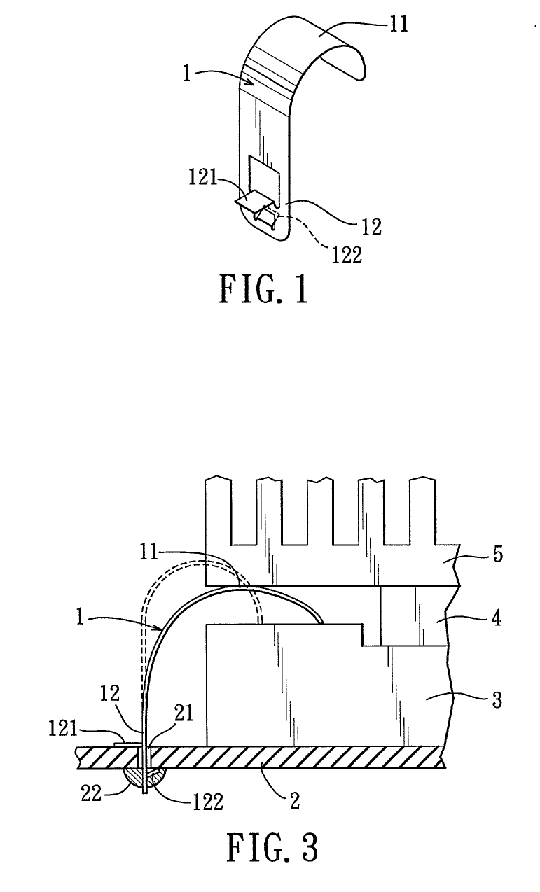

Referring to FIGS. 1 to 3, the preferred embodiment of a device for reducing electromagnetic interference of this invention is shown to be adapted for use in a processor assembly. The processor assembly includes a circuit board 2 with opposite first and second sides, a processor socket 3 mounted on the first side of the circuit board 2 and connected electrically to the circuit board 2, a central processing unit 4 having a heat-dissipating side and a contact side that is opposite to the heat-dissipating side and that is mounted on and connected electrically to the processor socket 3, and a conductive heat sink 5 disposed on and in contact with the heat-dissipating side of the central processing unit 4. The circuit board 2 is formed with a hole 21 that extends through the first and second sides thereof and that is disposed adjacent to the processor socket 3. The processor socket 3 is formed with a multiplicity of connecting holes 31.

As shown, the device includes a grounding spring plate 1 having a first end portion 11 adapted to contact the heat sink 5 and a second end portion 12 adapted to be mounted on the circuit board 2 so as to connect electrically with a ground terminal of the circuit board 2, thereby establishing electrical connection between the heat sink 5 and the ground terminal.

In this embodiment, the spring plate 1 is formed integrally from a metal plate by punching. The first end portion 11 of the spring plate 1 is generally inverted U-shaped and is adapted to be disposed underneath the heat sink 5 so as to be urged by the heat sink 5 toward the processor socket 3. The second end portion 12 of the spring plate 1 is adapted to extend through the hole 21 in the circuit board 2. The spring plate 1 is formed with a stop flange 121 that is adapted to abut against the first side of the circuit board 2, and a stop tab 122 that is adapted to abut against the second side of the circuit board 2. The stop flange 121 extends transversely from the second end portion 12 of the spring plate 1 so as to be adapted to rest on the first side of the circuit board 2. In this embodiment, the stop flange 121 is at an angle of about 90 degrees relative to the spring plate 1. The stop tab 122 has a lower edge connected to the second end portion 12 of the spring plate 1, and an upper edge adapted to abut against the second side of the circuit board 2. The stop tab 122 forms an angle, which is about 60 degrees in this embodiment, with the second end portion 12 of the spring plate 1. The stop flange 121 and the stop tab 122 extend in opposite directions relative to the second end portion 12 of the spring plate 1.

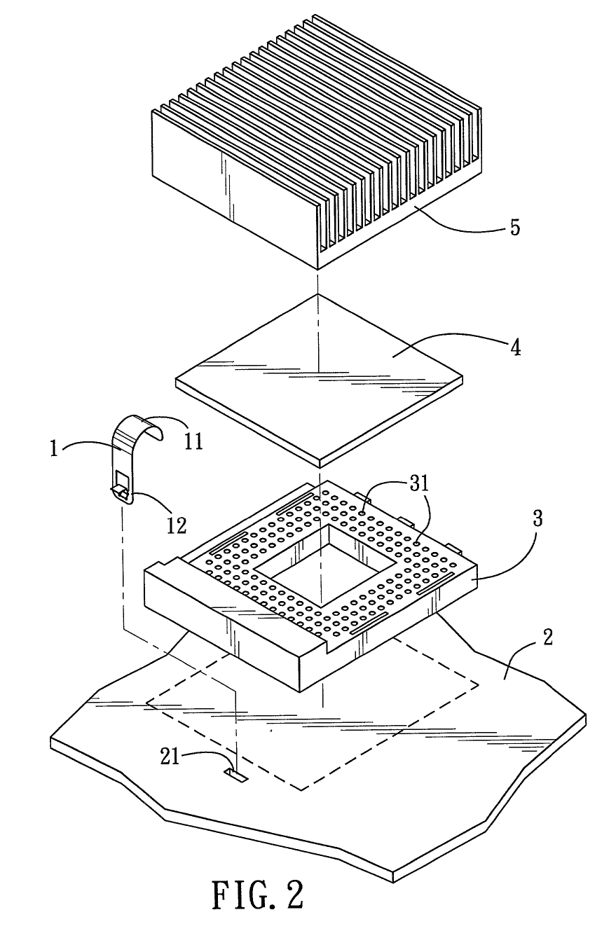

With further reference to FIG. 3, during assembly, the second end portion 12 of the spring plate 1 is extended into the hole 21 in the circuit board 2 prior to mounting the heat sink 5 or prior to mounting of the assembly of the heat sink 5 and the central processing unit 4 on the processor socket 3. At this point, the first end portion 11 is located above the processor socket 3. Since the stop tab 122 is at an angle relative to the second end portion 12, during extension of the second end portion 12 into the hole 21, the stop tab 122 will be resiliently deflected by the wall of the hole 21 so that the second end portion 12 can be smoothly extended through the hole 21 until the stop flange 121 abuts against the first side of the circuit board 2. Furthermore, the stop flange 121 and the stop tab 122 are configured to be spaced apart from each other by a distance equivalent to the thickness of the circuit board 2 such that when the stop flange 121 abuts against the first side of the circuit board 2, the stop tab 122 will be disposed out of the hole 21 and will abut against the second side of the circuit board 2 resiliently. As such, the spring plate 1 can be positioned securely on the circuit board 2 and is prevented from slippage from the hole 21. In addition, a solder ball 22 is formed on the second side of the circuit board 2 for retaining the second end portion 12 of the spring plate 1 on the circuit board 2 to thereby ensure electrical connection between the second end portion 12 and the ground terminal of the circuit board 2. Thereafter, the central processing unit 4 and the heat sink 5 are mounted in place in a conventional manner. Since the area of the bottom side of the heat sink 5 is generally larger than the area of the central processing unit 4, and since the heat sink 5 covers the processor socket 3, the heat sink 5 will come into contact with the first end portion 11 of the spring plate 1 above the processor socket 3 to thereby constitute a grounding circuit. As such, the electromagnetic waves from the central processing unit 4 can be conducted via the heat sink 5 to the ground terminal of the circuit board 2 to thereby reduce the electromagnetic interference caused thereby.

In view of the aforesaid, the present invention has the following advantages:

1. Reduced electromagnetic interference:

Since the electromagnetic waves generated during operation of the central processing unit can be conducted to the ground directly via the grounding spring plate, the reliability and stability of the system can be enhanced.

2. Highly flexible arrangement:

As the grounding spring plate does not take up a lot of space on the circuit board and can be disposed in any suitable position, it can be arranged to be disposed anywhere around the processor assembly so long as one end of the spring plate contacts the heat sink.

3. Simple construction:

The construction of the spring plate is very simple and facilitates production. Besides, mounting of the spring plate to the processor assembly is very convenient.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A device for reducing electromagnetic interference in a processor assembly that includes a circuit board with opposite first and second sides, a processor socket mounted on the first side of the circuit board and connected electrically to the circuit board, a central processing unit having a heat-dissipating side and a contact side that is opposite to the heat-dissipating side and that is mounted on and connected electrically to the processor socket, and a conductive heat sink in contact with the heat-dissipating side of the central processing unit, said device comprising:
a grounding spring plate having a first end portion adapted to contact the heat sink and a second end portion adapted to be mounted on the circuit board so as to connect electrically with a ground terminal of the circuit board, thereby establishing electrical connection between the heat sink and the ground terminal.

2. The device of claim 1, wherein said spring plate is formed integrally from a metal plate.

3. The device of claim 1, wherein said first end portion of said spring plate is generally inverted U-shaped and is adapted to be disposed underneath the heat sink so as to be urged by the heat sink toward the processor socket.

4. The device of claim 1, the circuit board being formed with a hole that extends through the first and second sides thereof and that is disposed adjacent to the processor socket, wherein said second end portion of said spring plate is adapted to extend through the hole in the circuit board, said spring plate being formed with a stop flange that is adapted to abut against the first side of the circuit board, and a stop tab that is adapted to abut against the second side of the circuit board.

5. The device of claim 4, wherein said stop flange extends transversely from said second end portion of said spring plate so as to be adapted to rest on the first side of the circuit board.

6. The device of claim 4, wherein said stop tab has a lower edge connected to said second end portion of said spring plate, and an upper edge adapted to abut against the second side of the circuit board, said stop tab forming an angle with said second end portion of said spring plate.

7. The device of claim 4, wherein said stop flange and said stop tab extend in opposite directions relative to said second end portion of said spring plate.

8. A processor assembly comprising:
a circuit board with opposite first and second sides, and a ground terminal;
a processor socket mounted on said first side of said circuit board and connected electrically to said circuit board;
a central processing unit having a heat-dissipating side and a contact side that is opposite to said heat-dissipating side and that is mounted on and connected electrically to said processor socket;
a conductive heat sink in contact with said heat-dissipating side of said central processing unit; and
a grounding spring plate having a first end portion in contact with said heat sink, and a second end portion mounted on said circuit board so as to connect electrically with said ground terminal of said circuit board, thereby establishing electrical connection between said heat sink and said ground terminal.

9. The processor assembly of claim 8, wherein said spring plate is formed integrally from a metal plate.

10. The processor assembly of claim 8, wherein said first end portion of said spring plate is generally inverted U-shaped and is disposed underneath said heat sink so as to be urged by said heat sink toward said processor socket.

11. The processor assembly of claim 8, wherein said circuit board is formed with a hole that extends through said first and second sides thereof and that is disposed adjacent to said processor socket, said second end portion of said spring plate being adapted to extend through said hole in said circuit board, said spring plate being formed with a stop flange that abuts against said first side of said circuit board, and a stop tab that abuts against said second side of said circuit board.

12. The processor assembly of claim 11, wherein said stop flange extends transversely from said second end portion of said spring plate so as to rest on said first side of said circuit board.

13. The processor assembly of claim 11, wherein said stop tab has a lower edge connected to said second end portion of said spring plate, and an upper edge abutting against said second side of said circuit board, said stop tab forming an angle with said second end portion of said spring plate.

14. The processor assembly of claim 11, wherein said stop flange and said stop tab extend in opposite directions relative to said second end portion of said spring plate.

15. The processor assembly of claim 8, further comprising a solder ball formed on said circuit board for retaining said second end portion of said spring plate on said circuit board.
